(19) United States
(12) Patent Application Publication
(10) Pub. No.: US 2008/0254590 A1
(43) Pub. Date: Oct. 16, 2008

(54) Fabrication process for silicon-on-insulator field effect transistors using high temperature nitrogen annealing

(76) Inventors: Eric E. Vogt, Maple Grove, MN (US); Paul S. Fechner, Plymouth, MN (US)

Correspondence Address: Honeywell International Inc.;Patent Services, 101 Columbia Road, Law Dept. AB2, POB2245, Morristown, NJ, 07962-2245, US

(21) Appl. No.: 11/783,598

(22) Filed: Apr. 10, 2007

(51) Int. Cl. H01L 21/76

(52) U.S. Cl. 438/400

(57) ABSTRACT

Disclosed is a method of fabricating a silicon-on-insulator (SOI) device that enables high device densities and mitigates variances in carrier mobility and saturation drain current (Idₛₐₜ). The fabrication method incorporates one or more high temperature nitrogen anneal processes. The high temperature nitrogen anneal nitridizes the interfaces between the n-well and p-well silicon islands and the buried oxide layer. The high temperature nitrogen anneal also nitridizes the interfaces between the n-well and p-well silicon islands and the shallow trench isolation structure. The presence of diffused nitrogen at these interfaces substantially prevents compressive stresses on the n-well and p-well silicon islands, and substantially prevents upward bending of the n-well and p-well silicon islands, which cause variances in carrier mobility and Idₛₐₜ.

### BACKGROUND OF THE INVENTION

1. Field of the Invention

The present invention generally relates to Silicon-On-Insulator (SOI) Field Effect Transistors (FETs). More particularly, the present invention relates to SOI FETs requiring reduced variances in carrier mobility and saturation drain current (Idₛₐₜ).

2. Discussion of the Related Art

SOI FETs have advantages that make them the preferred transistor architecture in many application. Advantages include high transconductance, radiation immunity, higher integration density, and excellent isolation. Further, SOI devices do not suffer from latch-up, parasitic capacitance, and leakage current problems that occur in traditional CMOS devices. A key disadvantage of SOI technology is the higher cost of fabrication. However, depending on the application, the advantages of SOI technology outweigh the fabrication costs.

Deep submicron (e.g., <0.25 μm) SOI fabrication processes typically use shallow trench isolation (hereinafter “STI”). In STI, a trench is etched between the n-well and p-well of an SOI device, and an oxide is deposited into the trench. STI is done to improve the isolation between the n-well and the p-well of an SOI device and enable greater fabrication densities.

FIG. 1 illustrates an NMOS portion, or a p-well portion of a related art SOI device 100. Related art SOI device 100 includes a silicon substrate 105; a buried oxide layer 115; an n-source/drain, which is an n-doped silicon island 120 having a p-doped region 122 under a gate oxide 125; and a poly-silicon gate structure 130. Related Art SOI device 100 further includes an STI oxide portion 135, which abuts n-source/drain 120 at Si-oxide interface 140.

A problem arises in deep submicron SOI fabrication in that compressive stresses (illustrated by arrows 145 and 150) arise during oxidation processes during device fabrication. Such oxidation processes include liner oxidation, first gate oxidation, and second gate oxidation. At each oxidation process, stresses 145 and 150 are compounded, which cause an upward bending of n-doped silicon island 120 (illustrated by arrow 155). The same problem occurs with the p-well silicon island (not shown) of SOI device 100.

The compressive stresses 145 and 150, and upward bending 155, result in a “squeezing” of silicon island 120, which results in extreme variations in carrier mobility, which in turn affects the saturation drain current (Idₛₐₜ) of the SOI device. Variations in carrier mobility may be as much as 50%. This may result in unpredictable performance variations of SOI devices on a single substrate, depending on the device layout, which may result in low fabrication yield, reduced device reliability, or required circuit redesign.

Referring again to FIG. 1, the compressive stress 150 of silicon island 120, and the resulting upward bending 160, become more pronounced as the distance 160 between poly-silicon gate structure 130 and STI portion 135 is reduced. As such, compressive stress 150 and bending 120 become more of a problem as devices become smaller and fabrication density increases.

What is needed is an SOI device fabrication process that mitigates compressive stresses and bending of silicon islands due to oxidation at the silicon/oxide interface where the n-wells and p-wells abut the STI structure.

### SUMMARY OF THE INVENTION

The present invention provides a fabrication process for SOI FETs using high temperature nitrogen annealing that obviates one or more of the aforementioned problems due to the limitations of the related art.

Accordingly, one advantage of the present invention is that it reduces carrier mobility variation in SOI devices.

Still another advantage of the present invention is that it improves the fabrication yield of SOI devices.

Additional advantages of the invention will be set forth in the description that follows, and in part will be apparent from the description, or may be learned by practice of the invention. The advantages of the invention will be realized and attained by the structure pointed out in the written description and claims hereof as well as the appended drawings.

To achieve these and other advantages, the present invention involves a method of fabricating a Silicon On Insulator device. The method comprises providing a blank material having a silicon base layer, a buried silicon dioxide layer, and a single crystal top silicon layer; diffusing nitrogen into the blank material so that nitrogen is diffused into an interface between the buried oxide layer and the top silicon layer; forming n-well and p-well silicon islands on the buried oxide layer; forming an STI trench between the n-well and p-well silicon islands; and forming an STI structure within the STI trench.

In another aspect of the present invention, the aforementioned and other advantages are achieved by a Silicon-On-Insulator (SOI) device. The device comprises a silicon substrate having a buried silicon dioxide layer and a single crystal top silicon layer; an n-well silicon island formed on the buried oxide layer, wherein the n-well silicon island includes the single crystal top silicon layer, wherein the n-well silicon island and the buried oxide layer have diffused nitrogen at a first interface where the n-well silicon island contacts the buried oxide layer, and wherein a first edge of the n-well silicon island at the first interface contacts the buried oxide layer substantially without an upward bending along the first edge; a p-well silicon island formed on the buried oxide layer, wherein the p-well silicon island and the buried oxide layer have diffused nitrogen at a second interface where the p-well silicon island contacts the buried oxide layer, and wherein a second edge of the n-well silicon island at the second interface contacts the buried oxide layer substantially without an upward bending along the second edge; and a shallow trench isolation structure having silicon oxide disposed between the n-well silicon island and the p-well silicon island, wherein the n-well silicon island has diffused nitrogen at a third interface where the n-well silicon island contacts the shallow trench isolation structure, and wherein the p-well silicon island has diffused nitrogen at a fourth interface where the p-well silicon island contacts the shallow trench isolation structure.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 illustrates an SOI FET according to the related art;

FIG. 2 illustrates an exemplary SOI device according to the present invention;

FIG. 3 is a diagram of an exemplary fabrication process of an SOI device according to the present invention; and

FIGS. 4A-4F illustrate an exemplary process of manufacturing an SOI device according to the present invention.

### DETAILED DESCRIPTION OF THE ILLUSTRATED EMBODIMENTS

The present invention incorporates one or more high temperature nitrogen anneal processes into an SOI fabrication process. By using a sufficiently high temperature, nitrogen is diffused into an SOI substrate to nitridize the oxide/silicon interfaces. In doing so, the nitridized oxide/silicon interfaces are subject to less oxidation during the oxidation processes of SOI fabrication. The presence of diffused nitrogen at the oxide/silicon interfaces reduces the oxidation rate at the interfaces. This results in reduced oxide formation at the oxide/silicon interfaces, which substantially mitigates the compressive stresses and upward bending of the silicon islands of an SOI device.

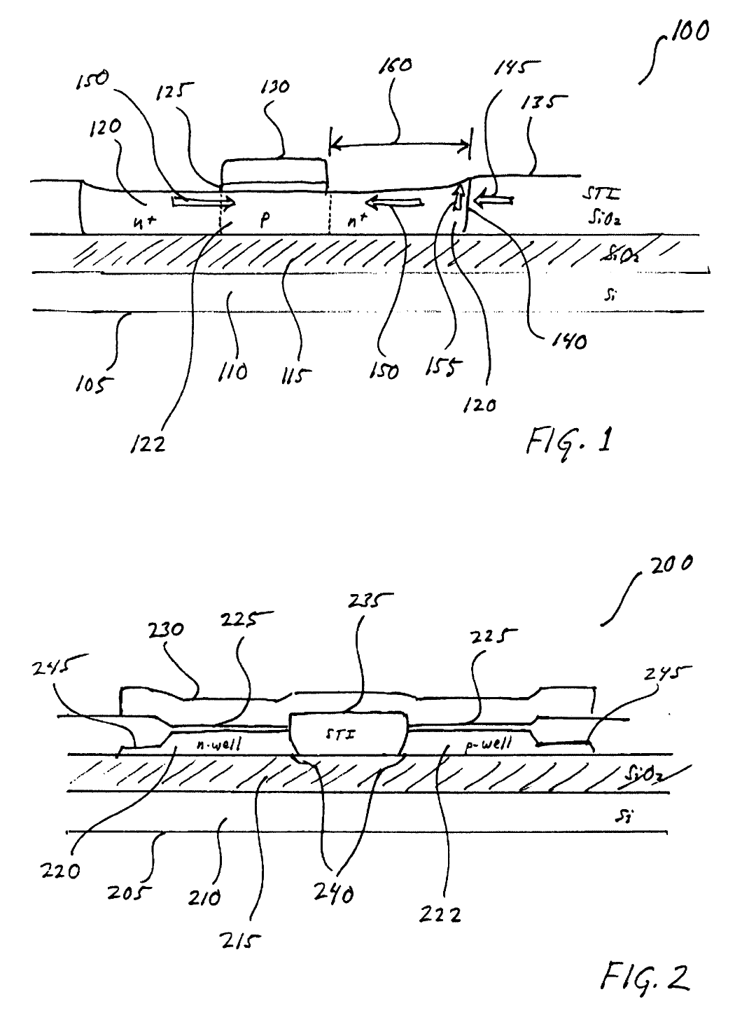

FIG. 2 illustrates an exemplary SOI device 200 according to the present invention. SOI device 200 includes a substrate 205, which includes a silicon base layer 210, and a buried oxide layer 215. Formed on buried oxide layer 215 is an n-well silicon island 220, a p-well silicon island 222, a shallow trench isolation (STI) structure 235, a gate oxide layer 225 formed on n-well silicon island 220 and p-well silicon island 222, and a poly-Si gate structure 230 formed on STI structure 235 and gate oxide layer 225. SOI device may also include a “body tie” structure 245 on each of n-well silicon island 220 and p-well silicon island 222. Body tie structure 245 is optional and is included herein for the purpose of describing exemplary SOI device 200. FIG. 2 further illustrates oxide/silicon interfaces 240 between STI structure 235 and n-well silicon island 220, and between STI structure 235 and p-well silicon island 222.

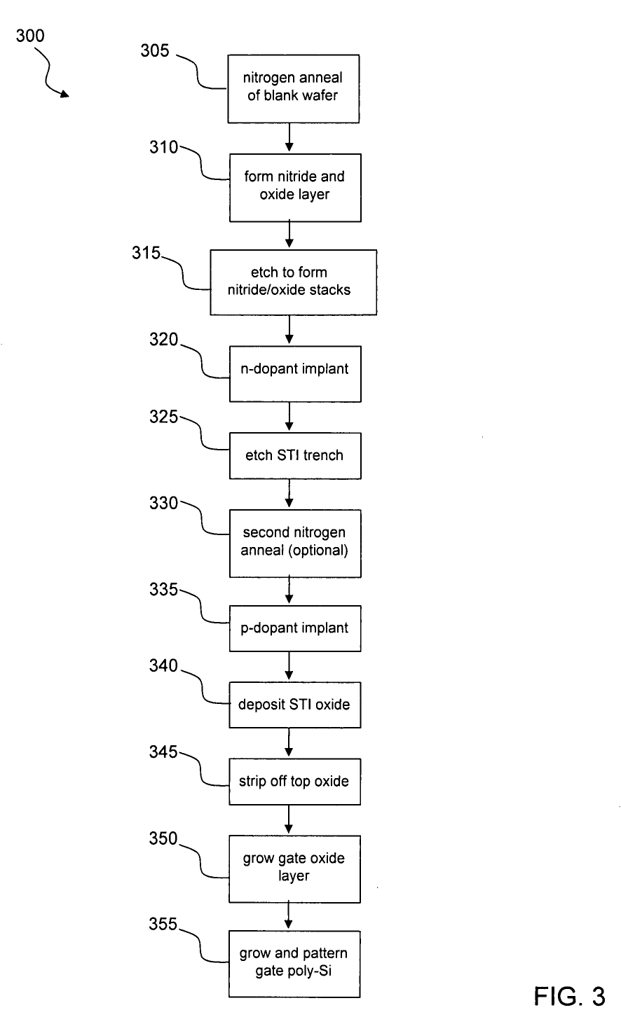

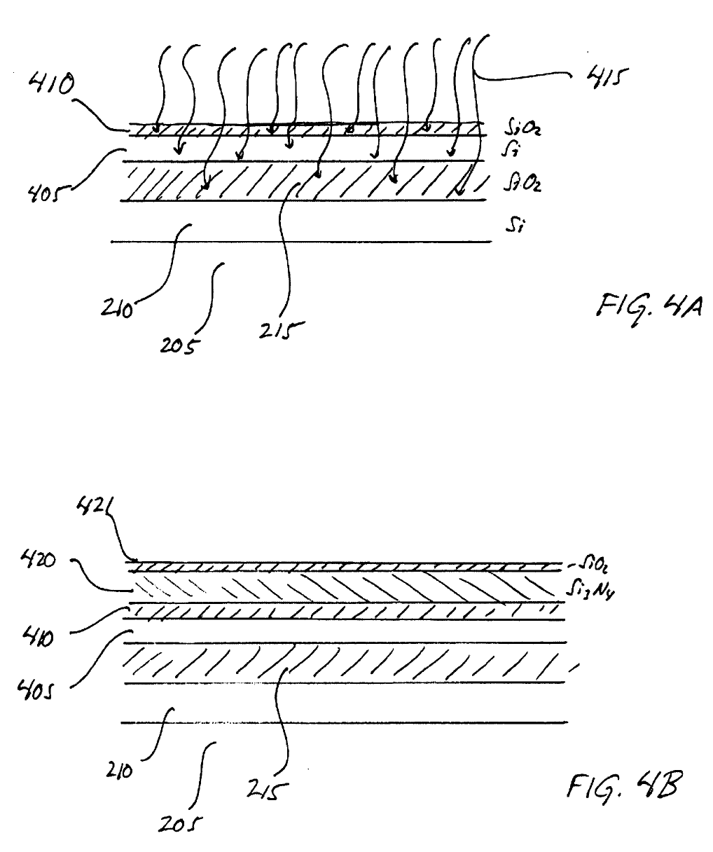

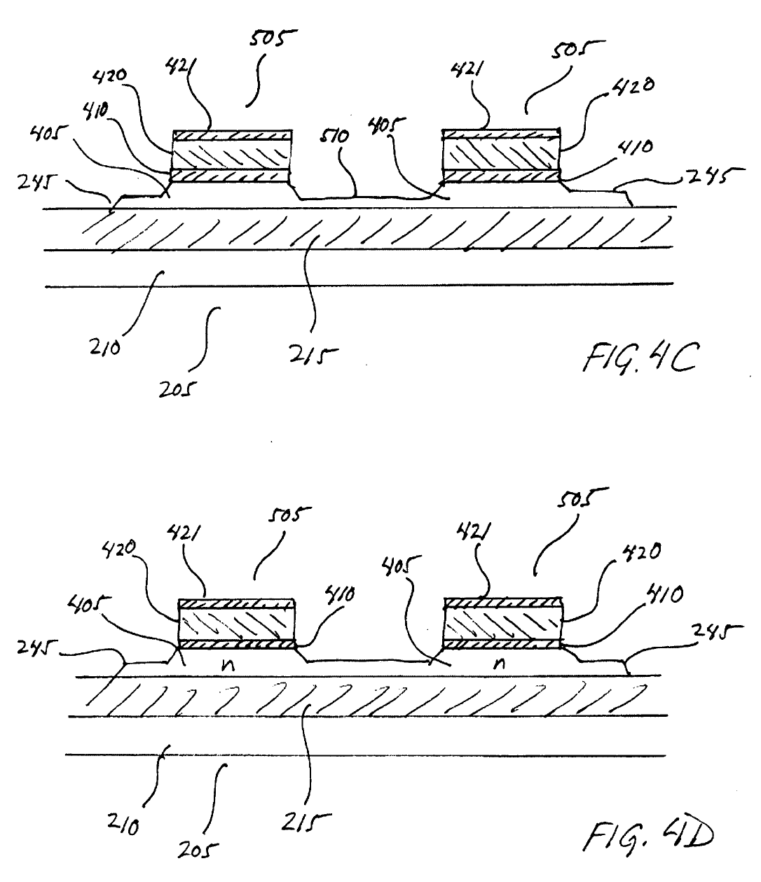

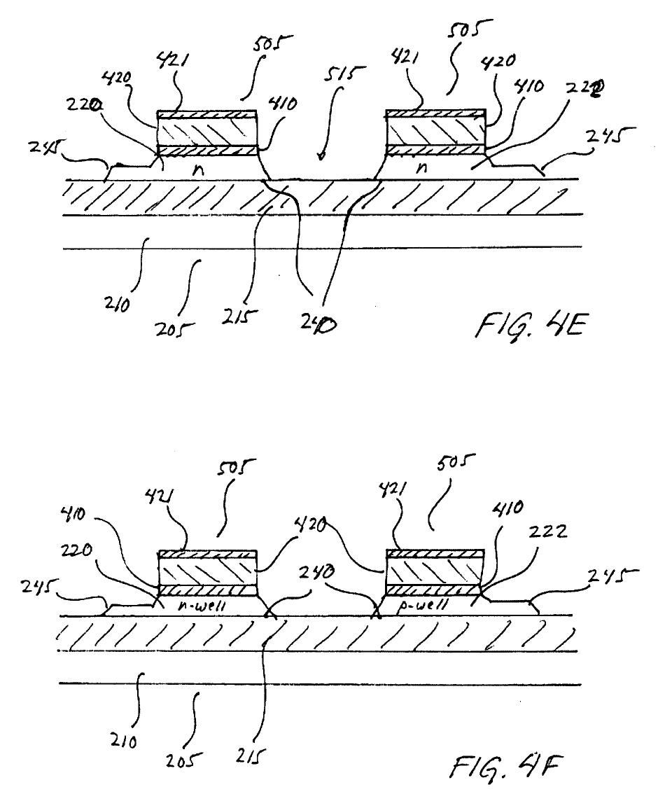

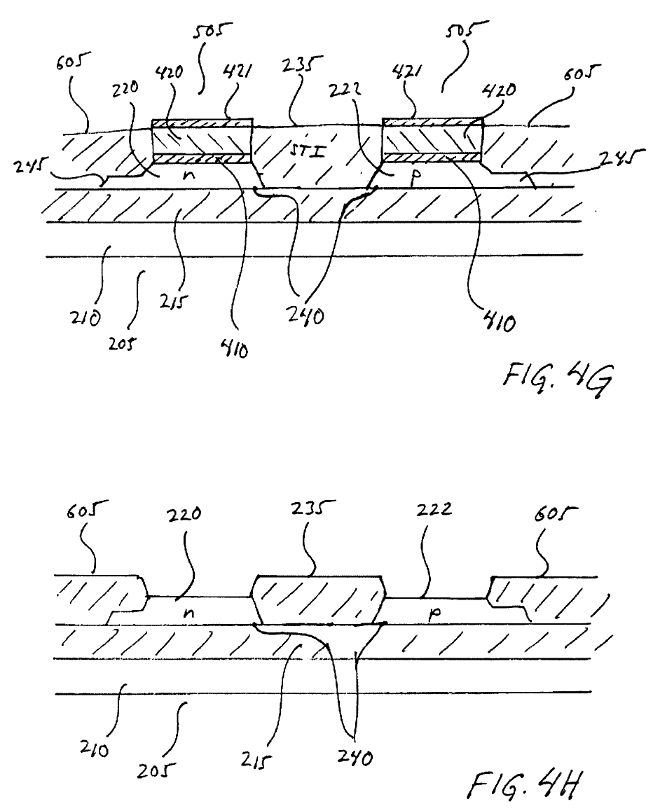

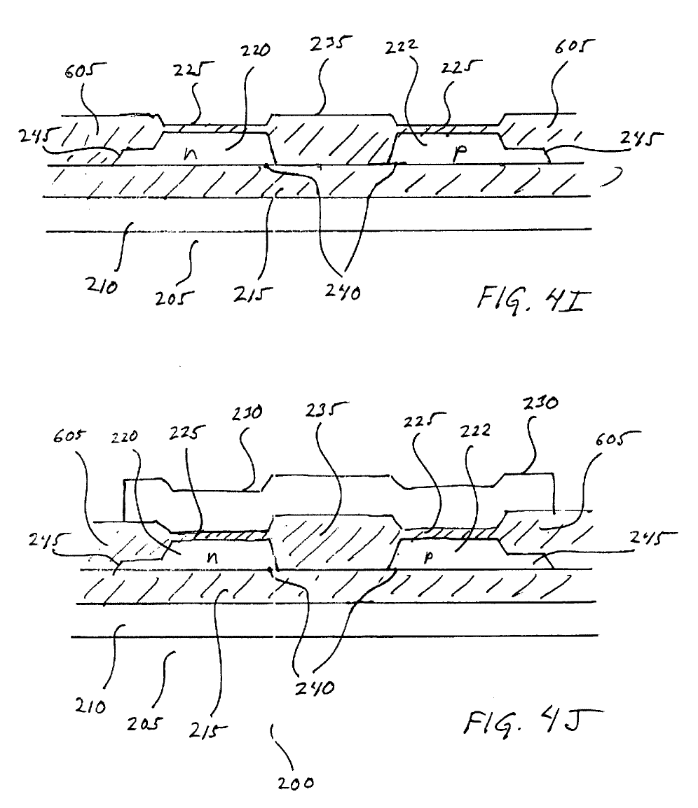

FIG. 3 illustrates an exemplary fabrication process of an SOI device according to the present invention; and FIGS. 4A-4F illustrate an exemplary process of manufacturing an SOI device according to the present invention.

Referring to FIGS. 3 and 4A, process 300 begins with a blank material wafer 205, which includes silicon base layer 210, buried oxide layer 215, an epitaxy or single crystal top silicon layer 405, and a field oxide layer 410.

In step 305, blank material wafer 205 is subjected to a high temperature nitrogen annealing process such that nitrogen 415 diffuses into the upper layers of blank material wafer 205, including the upper region of buried oxide layer 315. The high temperature nitrogen anneal process needs to be at a sufficient temperature in ambient nitrogen to nitridize the interface between buried oxide layer 215 and top silicon layer 405. In a preferred embodiment, the nitrogen concentration during the anneal process of step 305 may be between about 0.5% and about 2%; the ambient temperature during the anneal process may be between about 1300° C. and about 1325° C.; and this concentration and ambient temperature and may be maintained for a duration of approximately 2.5 hours.

Referring to FIG. 4B, in step 310, a silicon nitride layer 420 is deposited on field oxide layer 410. Next, a top oxide layer 421 is deposited on silicon nitride layer 420.

Referring to FIG. 4C, in step 315, top oxide layer 421, silicon nitride layer 420, field oxide layer 410 and a portion of top silicon layer 405 are etched to form nitride/oxide stacks 505. Optional to step 315, the etching process may leave a thin layer 510 of top silicon 405 between nitride/oxide stacks 505 and body tie regions 245 at the ends of the island structures that will later form n-well silicon island 220 and p-well silicon island 222. The thin layer 510 between the nitride/oxide stacks 505 is an artifact of the optional step of forming body tie regions 245. Thin layer 510 is later removed in subsequent processing below.

Referring to FIG. 4D, in step 320, an n-dopant is implanted into top silicon layer 405. The n-doped top silicon layer 405 will form the basis for n-well silicon island 220 illustrated in FIG. 2.

Referring to FIG. 4E, in step 325, thin layer 510 is etched to form STI trench 515, with silicon island interfaces 240. Further to step 325, a thin oxide may be formed (referred to as a liner oxidation) to anneal out surface states at silicon island interfaces 240 after etching. The liner oxidation step is optional. The nitrogen anneal performed in step 305, which nitridized top silicon layer 405 and the interface between top silicon layer 405 and buried oxide 215, substantially mitigates the upward bending at silicon island interfaces 240 that would otherwise occur. The upward bending at silicon island interfaces 240 is caused by oxide growth at the interface between buried oxide layer 215 and top silicon layer 405. Because the presence of diffused nitrogen reduces the oxidation rate at the interface between top silicon layer 405 and buried oxide 215, compressive stresses in n-well silicon island 220 and p-well silicon island 222, and upward bending at the corners of n-well silicon island 220 and p-well silicon island 222, are substantially mitigated.

Referring to FIG. 4E, step 330 is an optional second high temperature nitrogen anneal step, in which additional nitrogen is diffused into the interfaces between n-doped top silicon layer 405 and buried oxide layer 215.

Referring to FIG. 4F, in step 335, a p-dopant is implanted into a portion of top silicon layer 405. A mask is used to implant the p-dopant into one of the silicon islands formed in the etching of STI trench 515 in step 325. Step 335 results in n-well silicon island 220 and p-well silicon island 222.

Referring to FIG. 4G, in step 340, a thick oxide layer is formed in STI trench 515 (illustrated in FIG. 4E) and above body tie regions 245, forming STI structure 235 and thick oxide regions 605. The thick oxide layer may completely cover nitride/oxide stacks 505. The presence of nitride at silicon island interfaces 240 (due to nitridization performed in step 305 and optionally in step 330) reduces the oxidation rate at silicon island interfaces 240. As mentioned above, by reducing the oxidation rate at silicon island interfaces 240, compressive stresses in n-well silicon island 220 and p-well silicon island 222, and upward bending at the corners of n-well silicon island 220 and p-well silicon island 222, are substantially mitigated.

Further to step 340, the thick oxide layer formed in step top oxide layer 421 is removed using a chemical/mechanical polishing technique that is known to the art. The chemical/mechanical polish erodes the top surface of the thick oxide layer until the polishing process reaches the silicon nitride layer 420 in the nitride/oxide stacks 505. Accordingly, nitride/oxide stacks 505 serve as stops for the chemical/mechanical polishing process.

Referring to FIG. 4H, in step 345, the nitride/oxide stacks 505, and the field oxide layer 410 under the nitride/oxide stacks 505, are stripped off, thereby exposing top portions of n-well silicon island 220 and p-well silicon island 222.

Referring to FIG. 4I, in step 350, a thin oxide layer is grown on top of n-well silicon island 220, p-well silicon island 222, STI structure 235, and thick oxide regions 605. Again, the presence of nitride at silicon island interfaces 240, which is due to nitridization performed in step 305 and optionally in step 330, reduces the oxidation rate at silicon island interfaces 240 during the oxidation performed in step 350.

Referring to FIG. 4J, in step 355, poly-Si gate structure 230 is formed and patterned.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of fabricating a Silicon On Insulator device, comprising:
providing a blank material having a silicon base layer, a buried silicon dioxide layer, and a single crystal top silicon layer;
diffusing nitrogen into the blank material so that nitrogen is diffused into an interface between the buried oxide layer and the top silicon layer;
forming n-well and p-well silicon islands on the buried oxide layer;
forming an STI trench between the n-well and p-well silicon islands; and
forming an STI structure within the STI trench.

2. The method of claim 1, wherein the diffusing of nitrogen comprises diffusing nitrogen at a nitrogen concentration between about 0.5 and about 2%.

3. The method of claim 2, wherein the diffusing of nitrogen comprises diffusing nitrogen at an ambient temperature between about 1300° C. and about 1325° C.

4. The method of claim 3, wherein the diffusing of nitrogen comprises diffusing nitrogen for approximately 2.5 hours.

5. The method of claim 1, further comprising forming a silicon nitride layer and a top oxide layer on the top silicon layer before diffusing nitrogen into the blank material.

6. The method of claim 5, further comprising forming a first nitride/oxide stack and a second nitride stack out of the silicon nitride layer and the top silicon layer.

7. The method of claim 1, further comprising diffusing nitrogen into the STI trench after forming the STI trench.

8. A Silicon-On-Insulator (SOI) device, comprising:
a silicon substrate having a buried silicon dioxide layer and a single crystal top silicon layer;
an n-well silicon island formed on the buried oxide layer, wherein the n-well silicon island includes the single crystal top silicon layer, wherein the n-well silicon island and the buried oxide layer have diffused nitrogen at a first interface where the n-well silicon island contacts the buried oxide layer, and wherein a first edge of the n-well silicon island at the first interface contacts the buried oxide layer substantially without an upward bending along the first edge;
a p-well silicon island formed on the buried oxide layer, wherein the p-well silicon island and the buried oxide layer have diffused nitrogen at a second interface where the p-well silicon island contacts the buried oxide layer, and wherein a second edge of the n-well silicon island at the second interface contacts the buried oxide layer substantially without an upward bending along the second edge; and
a shallow trench isolation structure having silicon oxide disposed between the n-well silicon island and the p-well silicon island,
wherein the n-well silicon island has diffused nitrogen at a third interface where the n-well silicon island contacts the shallow trench isolation structure, and wherein the p-well silicon island has diffused nitrogen at a fourth interface where the p-well silicon island contacts the shallow trench isolation structure.
